(19) United States
(12) Patent Application Publication
(10) Pub. No.: US 2017/0084675 A1
(43) Pub. Date: Mar. 23, 2017

(54) ORGANIC LIGHT-EMITTING DISPLAY DEVICES AND METHODS OF MANUFACTURING ORGANIC LIGHT-EMITTING DISPLAY DEVICES

(71) Applicant: Samsung Display Co., Ltd., Yongin-si (KR)

(72) Inventors: Ho-Jin YOON, Hwaseong-si (KR); Hee-Kyung KIM, Busan (KR); Ji-Hoon SONG, Osan-si (KR); Mu-Gyeom KIM, Hwaseong-si (KR)

(21) Appl. No.: 15/139,445

(22) Filed: Apr. 27, 2016

(30) Foreign Application Priority Data
Sep. 18, 2015 (KR) 10-2015-0132046

(51) Int. Cl. H01L 27/32

(52) U.S. Cl. CPC H01L 27/3246; H01L 27/3251

(57) ABSTRACT

An organic light-emitting display device may include a first substrate, a first electrode disposed on the first substrate, a pixel defining layer disposed on the first substrate and defining a pixel opening thereof which exposes a portion of the first electrode, an organic light-emitting layer disposed on the exposed portion of the first electrode, a second electrode disposed on the organic light-emitting layer, a capping layer disposed on the second electrode and extending to contact the pixel defining layer, a second substrate opposite to the first substrate, and a dispersion layer disposed on a bottom surface of the second substrate. The dispersion layer may absorb an outgas generated by the pixel defining layer.

This application claims priority to Korean Patent Application No. 10-2015-0132046, filed on Sep. 18, 2015, and all the benefits accruing therefrom under 35 U.S.C. §119, the content of which in its entirety is herein incorporated by reference.

### BACKGROUND

1. Field

Exemplary embodiments relate to organic light-emitting display devices and methods of manufacturing organic light-emitting display devices. More particularly, exemplary embodiments relate to organic light-emitting display devices including a capping layer and a dispersion layer, and methods of manufacturing the organic light-emitting display devices.

2. Description of the Related Art

An organic light-emitting display device may have an organic light-emitting structure including a hole injection layer, an electron injection layer, and an organic light-emitting layer formed therebetween. In the organic light-emitting display device, light may be generated as excitons, that are the combination of holes injected from the hole injection layer and electrons injected from the electron injection layer, fall from an excited state to a ground state. The organic light-emitting display device may not include a separate light source to generate light, and thus the organic light-emitting display device may have relatively small thickness and light weight as well as relatively low power consumption. Furthermore, the organic light-emitting display device may have relatively wide viewing angle, high contrast and high response speed, etc.

In the organic light-emitting display device, a planarization layer that protects a transistor driving the organic light-emitting structure and planarizes a top surface of the transistor may be disposed, and a pixel defining layer separating pixels may be disposed over the planarization layer. The planarization layer and the pixel defining layer may include an organic material.

### SUMMARY

Exemplary embodiments provide an organic light-emitting display device including a dispersion layer that reduces or effectively prevents a pixel shrinkage caused by an outgassing from a pixel defining layer.

Exemplary embodiments provide a method of manufacturing an organic light-emitting display device including a dispersion layer that reduces or effectively prevents a pixel shrinkage by an outgassing from a pixel defining layer.

According to exemplary embodiments, an organic light-emitting display device may include a first substrate, a first electrode disposed on the first substrate, a pixel defining layer disposed on the first substrate and defining a pixel opening thereof which exposes a portion of the first electrode, an organic light-emitting layer disposed on the exposed portion of the first electrode, a second electrode disposed on the organic light-emitting layer, a capping layer disposed on the second electrode and extending to contact the pixel defining layer, a second substrate opposite to the first substrate, and a dispersion layer disposed on a bottom surface of the second substrate to face the pixel defining layer with respect to the capping layer.

In exemplary embodiments, the dispersion layer may absorb an outgas generated by the pixel defining layer.

In exemplary embodiments, an end portion of the capping layer may contact the pixel defining layer.

In exemplary embodiments, a thickness of the dispersion layer may be in a range of about 54 nanometers (nm) to about 150 nm.

In exemplary embodiments, the capping layer may include an organic material.

In exemplary embodiments, the dispersion layer may include an organic material.

In exemplary embodiments, the dispersion layer may have substantially a same material as the capping layer.

In exemplary embodiments, the dispersion layer may be disposed on an entirety of the bottom surface of the second substrate.

In exemplary embodiments, the organic light-emitting display device may further include a first reflective layer disposed between the second substrate and the dispersion layer.

In exemplary embodiments, the first reflective layer may include a reflective portion corresponding to the pixel defining layer, the reflective portion may define an opening portion of the first reflective layer, and the opening portion may be surrounded by the reflective portion and correspond to the first electrode.

In exemplary embodiments, the first reflective layer may include at least one of aluminum (Al), silver (Ag), gold (Au), platinum (Pt), nickel (Ni), copper (Cu) and tungsten (W).

In exemplary embodiments, the dispersion layer may be disposed on an entirety of the first reflective layer.

In exemplary embodiments, the dispersion layer may be disposed on a portion of the first reflective layer.

In exemplary embodiments, the dispersion layer may be disposed overlapping the opening portion of the first reflective layer and non-overlapping the reflective portion of the first reflective layer.

In exemplary embodiments, the organic light-emitting display device may further include a second reflective layer disposed between the first reflective layer and the dispersion layer.

In exemplary embodiments, the second reflective layer may be disposed on an entirety of the first reflective layer.

In exemplary embodiments, the second reflective layer may include at least one of silver (Ag) and indium tin oxide (“ITO”).

In exemplary embodiments, the dispersion layer disposed on the bottom surface of the second substrate may define a space with the capping layer, and the organic light-emitting display device may further include a filling member in the space between the capping layer and the dispersion layer.

In exemplary embodiments, the filling member may include silicon.

According to exemplary embodiments, in a method of manufacturing an organic light-emitting display device, a first electrode may be formed on a first substrate, and a pixel defining layer may be formed on the first substrate. The pixel defining layer may define a pixel opening thereof which exposes a portion of the first electrode. An organic light-emitting layer may be formed on the exposed portion of the first electrode, and a second electrode may be formed on the organic light-emitting layer. A capping layer may be formed on the second electrode and extend to contact the pixel defining layer. A dispersion layer that absorbs an outgas generated from the pixel defining layer may be formed on a second substrate, and the second substrate may be combined with the first substrate to dispose the dispersion layer facing the capping layer.

In exemplary embodiments, the dispersion layer may be formed using an organic material.

In exemplary embodiments, the capping layer and the dispersion layer may be formed using substantially a same material.

According to exemplary embodiments, the organic light-emitting display device may include the dispersion layer disposed on the bottom surface of the second substrate. Accordingly, the outgas generated from the pixel defining layer may be transferred to the dispersion layer through the filling member, and the amount of the outgas transferred to the organic light-emitting layer through the capping layer may be decreased.

According to some exemplary embodiments, the organic light-emitting display device may further include the first reflective layer reflecting an external light, so that the dispersion layer may transmit the external light and improve a quality of a mirror function as well as absorb the outgas.

### BRIEF DESCRIPTION OF THE DRAWINGS

Illustrative, non-limiting exemplary embodiments will be more clearly understood from the following detailed description taken in conjunction with the accompanying drawings.

FIG. 1 is a top plan view illustrating an exemplary embodiment of an organic light-emitting display device in accordance with the invention.

FIG. 2 is a cross-sectional view illustrating an exemplary embodiment of the organic light-emitting display device in FIG. 1 taken along line I-I′ in FIG. 1.

FIG. 3 is a cross-sectional view illustrating an exemplary embodiment of the organic light-emitting display device in FIG. 1 taken along line II-II′ in FIG. 1.

FIG. 4 is a cross-sectional view of an organic light-emitting display device for explaining an outgassing to a dispersion layer thereof.

FIGS. 5 and 6 are cross-sectional views illustrating other exemplary embodiments of the organic light-emitting display device in FIG. 1 taken along line II-II′ in FIG. 1.

FIG. 7 is a cross-sectional view illustrating still another exemplary embodiment of the organic light-emitting display device in FIG. 1 taken along line II-II′ in FIG. 1.

FIGS. 8 to 10 are cross-sectional views illustrating an exemplary embodiment of a method of manufacturing an organic light-emitting display device in accordance with the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms.

These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In an organic light-emitting display device, an organic light-emitting structure thereof may include a hole injection layer, an electron injection layer, and an organic light-emitting layer formed therebetween, and a planarization layer and a pixel defining layer thereof may include an organic material. The pixel defining layer including the organic material may generate an outgas due to relatively short-term or long-term chemical dissolution thereof. The outgas may be injected into the organic light-emitting layer of the organic light-emitting structure, and may degrade the organic light-emitting structure, so that a pixel shrinkage may be undesirably induced or a lifetime of the pixels may be undesirably decreased.

Hereinafter, exemplary embodiments of organic light-emitting display devices and methods of manufacturing organic light-emitting display devices in accordance with the invention will be explained in detail with reference to the accompanying drawings.

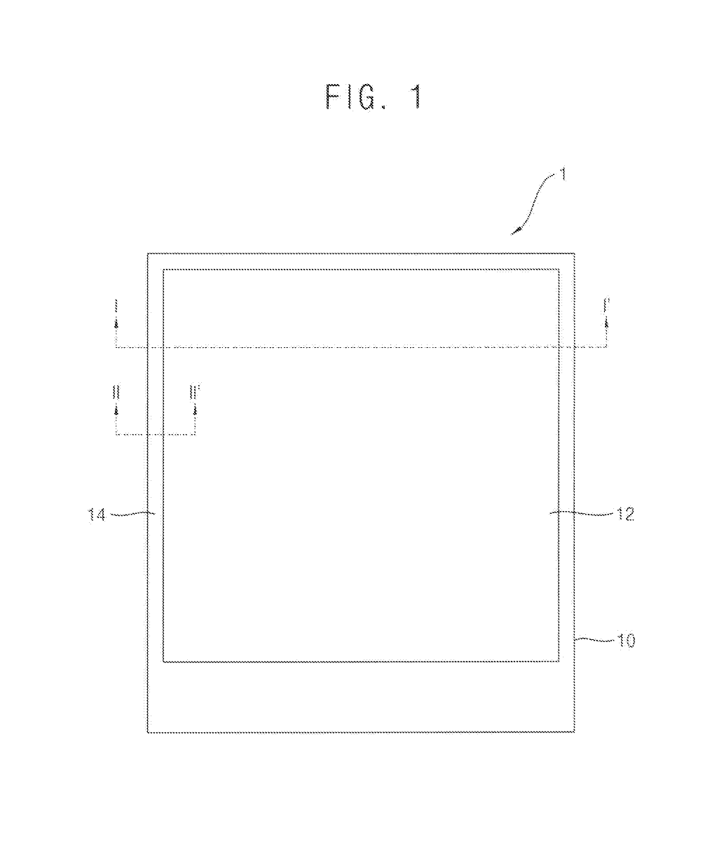

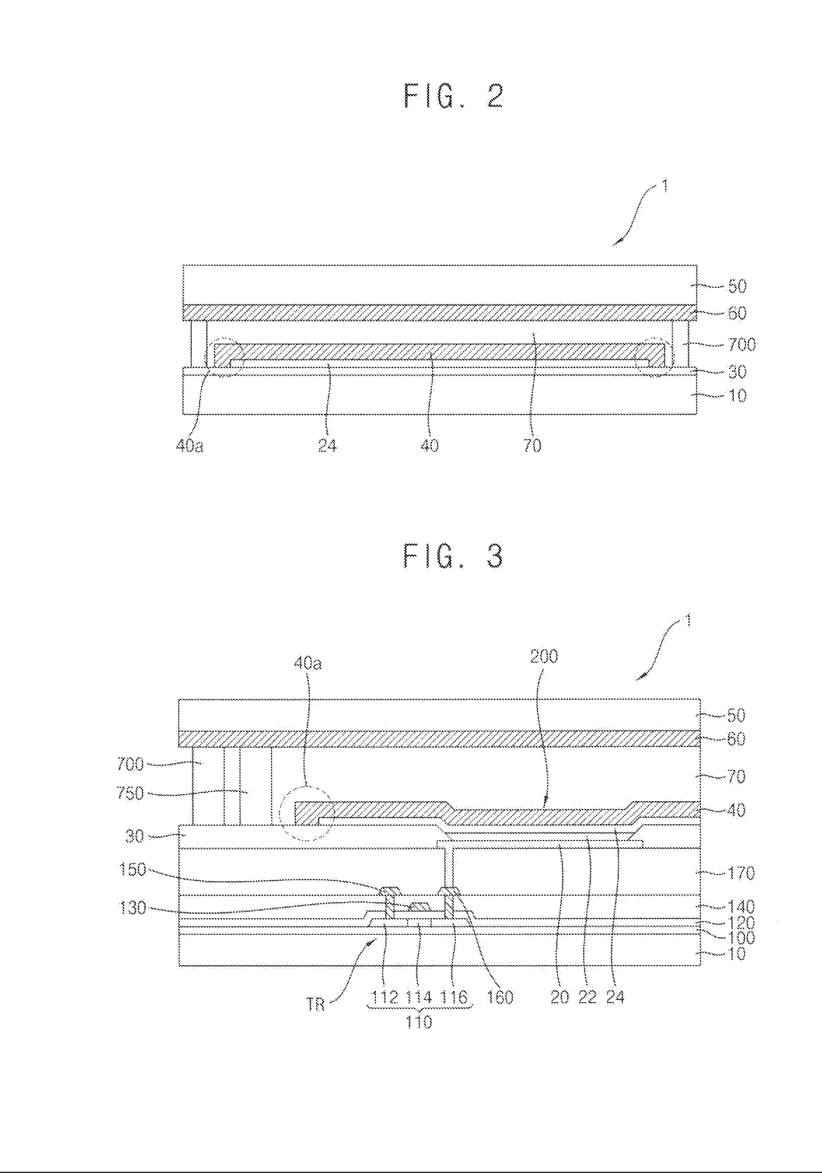

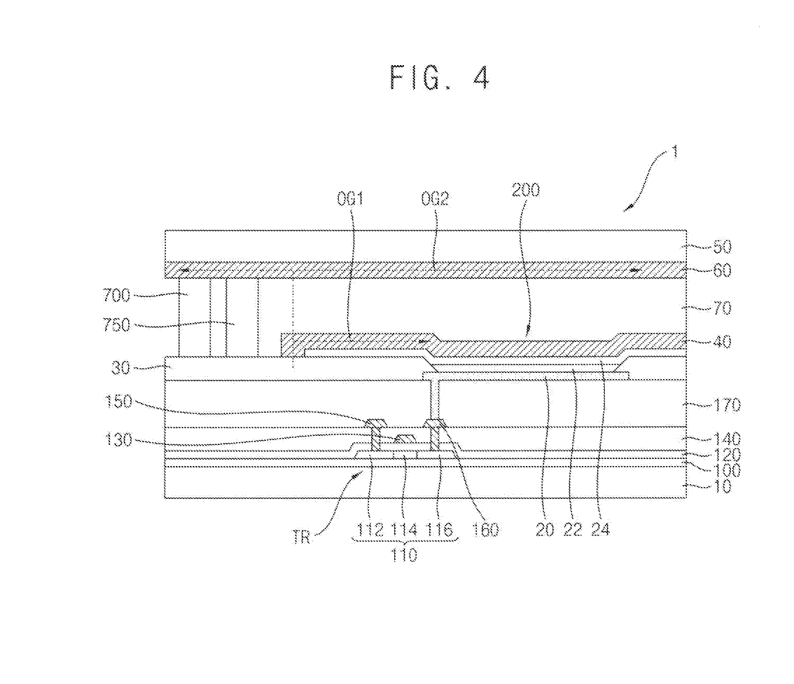

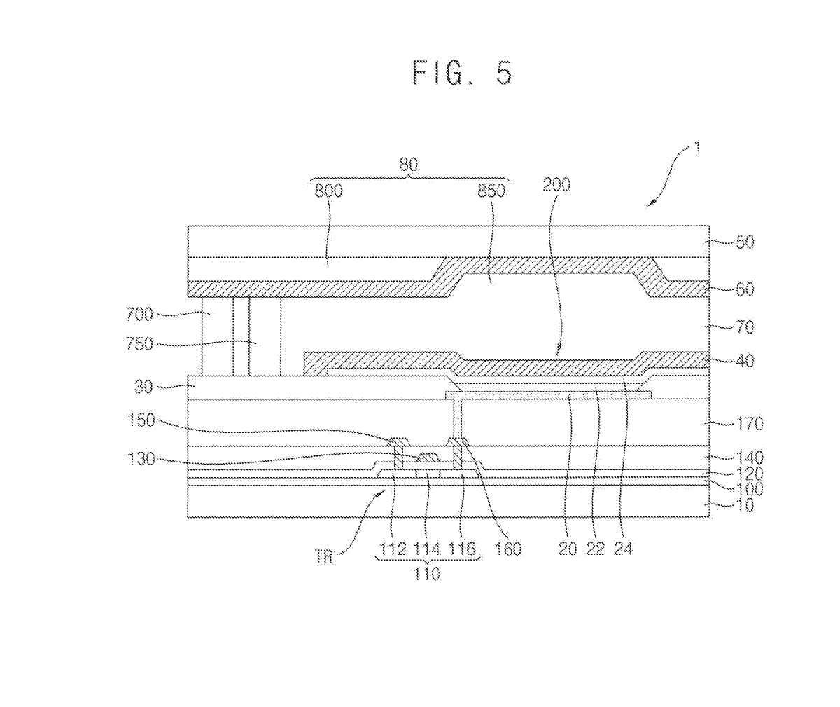

FIG. 1 is a top plan view illustrating an exemplary embodiment of an organic light-emitting display device in accordance with the invention. FIG. 2 is a cross-sectional view illustrating an exemplary embodiment of the organic light-emitting display device in FIG. 1 taken along line I-I′ in FIG. 1. FIG. 3 is a cross-sectional view illustrating an exemplary embodiment of the organic light-emitting display device in FIG. 1 taken along line II-II′ in FIG. 1. FIG. 4 is a cross-sectional view of an organic light-emitting display device for explaining an outgassing to a dispersion layer thereof.

Referring to FIGS. 1 to 3, an organic light-emitting display device 1 may include a transistor TR, an organic light-emitting structure 200, a pixel defining layer 30 and a capping layer 40 on a first substrate 10, a dispersion layer 60 on a second substrate 50, etc. The first substrate 10 and the second substrate 50 may serve as base substrates of lower and upper (display) substrates of the organic light-emitting display device 1. In exemplary embodiments, the organic light-emitting display device 1 may further include a filling member 70. The filling member 70 may be disposed between the upper and lower substrates of the organic light-emitting display device 1.

The first substrate 10 may include a transparent insulation substrate such as a glass substrate, a quartz substrate, a plastic substrate, etc. Alternatively, the first substrate 10 may include a flexible substrate.

A display region 12 and a peripheral (e.g., non-display) region 14 that substantially surrounds the display region 12 may be defined on the first substrate 10. A plurality of pixels may be disposed in the display region 12 of the organic light-emitting display device 1 for displaying images. In an exemplary embodiment, for example, the plurality of pixels may be arranged in a substantial matrix structure on the first substrate 10 in the display region 12 thereof. Each of the plurality of pixels may include the transistor TR and the organic light-emitting structure 200.

Referring to FIG. 3, a buffer layer 100 may be disposed on the first substrate 10. The buffer layer 100 may reduce or effectively prevent vapor or oxygen from being permeated toward upper structures on the first substrate 10 such as including the transistor TR and the organic light-emitting structure 200. Additionally, the buffer layer 100 may reduce or effectively prevent diffusion of ions from the first substrate 10 to the upper structures. In an exemplary embodiment, for example, the buffer layer 100 may include a silicon compound such as silicon oxide (SiOx), silicon nitride (SiNx), silicon oxynitride (SiOxNy), etc. The buffer layer 100 may have a single layer structure or a multi-layer structure.

The transistor TR may be disposed on the buffer layer 100. The transistor TR may include an active pattern 110, a gate insulation layer 120, a gate electrode 130, an insulation interlayer 140, a source electrode 150, a drain electrode 160, etc. As illustrated in FIG. 3, the transistor TR may have a top gate configuration in which the gate electrode 130 is disposed over the active pattern 110, however, the configuration of the transistor TR may not be limited thereto. In some exemplary embodiments, the transistor TR may have a bottom gate configuration in which the gate electrode 130 is disposed under the active pattern 110.

The active pattern 110 may be disposed on the buffer layer 100. In an exemplary embodiment, for example, the active pattern 110 may include a material containing silicon or oxide semiconductor. The active pattern 110 may include a source region 112, a drain region 116, and a channel region 114 disposed therebetween.

The gate insulation layer 120 may be disposed on the buffer layer 100 to substantially cover the active pattern 110. In an exemplary embodiment, for example, the gate insulation layer 120 may include a silicon compound such as silicon oxide, silicon nitride, and silicon oxy nitride, or may include metal oxide such as aluminum oxide (AlOx), titanium oxide (TiOx), and hafnium oxide (HfOx).

The gate electrode 130 may be disposed on the gate insulation layer 120. In exemplary embodiments, the gate electrode 130 may locate over and overlap the channel region 114 of the active pattern 110. In an exemplary embodiment, for example, the gate electrode 130 may include gold (Au), silver (Ag), copper (Cu), nickel (Ni), platinum (Pt), aluminum (Al), molybdenum (Mo), and/or titanium (Ti).

The insulation interlayer 140 may be disposed on the gate insulation layer 120 to substantially cover the gate electrode 130. The insulation interlayer 140 may electrically insulate the gate electrode 130 from each of the source electrode 150 and the drain electrode 160. In an exemplary embodiment, for example, the insulation interlayer 140 may include a silicon compound such as silicon oxide, silicon nitride, silicon oxy nitride, etc.

The source electrode 150 and the drain electrode 160 may be disposed on the insulation interlayer 140. Each of the source electrode 150 and the drain electrode 160 may make contact with the active pattern 110 through the gate insulation layer 120 and the insulation interlayer 140 such as at a contact hole in the gate insulation layer 120 and the insulation interlayer 140. Specifically, the source electrode 150 may be electrically connected to the source region 112 of the active pattern 110, and the drain electrode 160 may be electrically connected to the drain region 116 of the active pattern 110. In an exemplary embodiment, for example, each of the source electrode 150 and drain electrode 160 may include gold, silver, copper, nickel, platinum, aluminum, molybdenum, and/or titanium.

A planarization layer 170 may be disposed on the insulation interlayer 140 to substantially cover the transistor TR. The planarization layer 170 may have a substantially flat upper surface. In an exemplary embodiment, for example, the planarization layer 170 may include a silicon compound such as silicon oxide, silicon nitride, silicon oxy nitride, etc. Alternatively, the planarization layer 170 may include an organic material such as polyimide, acryl, etc.

As illustrated in FIG. 3, the organic light-emitting structure 200 may include a first electrode 20, an organic light-emitting layer 22, a second electrode 24, etc.

The first electrode 20 may be disposed on the planarization layer 170. The first electrode 20 may be in contact with the drain electrode 160 through the planarization layer 170, such as at a contact hole in the planarization layer 170. Thus, the organic light-emitting structure 200 may be electrically connected to the transistor TR. In an exemplary embodiment, for example, the first electrode 20 may correspond to an anode of the organic light-emitting structure 200. When the organic light-emitting display device 1 is a top emission type organic light-emitting display device, the first electrode 20 may act as a reflective electrode. Alternatively, the first electrode 20 may act as a transparent electrode where the organic light-emitting display device 1 is a bottom emission type organic light-emitting display device. In an exemplary embodiment, for example, the first electrode 20 may include silver (Ag), magnesium (Mg), aluminum (Al), platinum (Pt), gold (Au), nickel (Ni), iridium (Ir), chrome (Cr), indium tin oxide (“ITO”), indium zinc oxide (“IZO”), zinc oxide (ZnO), and/or indium gallium oxide (“IGO”).

A pixel defining layer 30 may be disposed on the planarization layer 170 while partially exposing the first electrode 20. The pixel defining layer 30 may be substantially disposed over the entire first substrate 10. The pixel defining layer 30 may have a pixel opening that may expose the portion of the first electrode 20. In an exemplary embodiment, for example, the pixel defining layer 30 may include an organic material.

The organic light-emitting layer 22 may be disposed on the exposed first electrode 20 and on a portion of the pixel defining layer 30. In an exemplary embodiment, when the organic light-emitting layer 22 includes an organic material having a relatively low molecular weight, a hole injection layer and a hole transport layer may be disposed under the organic light-emitting layer 22, and an electron transport layer and an electron injection layer may be disposed over the organic light-emitting layer 22. In another exemplary embodiment, when the organic light-emitting layer 22 includes an organic material having a relatively high molecular weight, the hole transport layer may be disposed under the organic light-emitting layer 22.

The second electrode 24 may be disposed on the organic light-emitting layer 22. The second electrode 24 may be substantially disposed in the entire display region 12. In an exemplary embodiment, for example, the second electrode 24 may correspond to a cathode of the organic light-emitting structure 200. When the organic light-emitting display device 1 is the top emission type organic light-emitting display device, the second electrode 24 may be the transparent electrode. Alternatively, when the organic light-emitting display device 1 is the bottom emission type organic light-emitting display device, the second electrode 24 may be the reflective electrode. In an exemplary embodiment, for example, the second electrode 24 may include silver, magnesium, aluminum, platinum, gold, nickel, iridium, chrome, indium tin oxide, indium zinc oxide, zinc oxide, and/or indium gallium oxide.

A sealing member 700 may be disposed on the pixel defining layer 30. The sealing member 700 may be located in the peripheral region 14. The sealing member 700 may combine the second substrate 50 with the first substrate 10 and/or combine the lower substrate with the upper substrate. A space may be defined between the lower and upper substrates (or the first and second substrates 50) combined with each other.

A getter 750 may be disposed on the pixel defining layer 30. The getter 750 may be located in the peripheral region 14. The getter 750 may react with moisture and/or oxygen existing in a space between the first substrate 10 and the second substrate 50 combined with each other, resulting in efficient removal of the moisture and/or oxygen. Therefore, the getter 750 may reduce or effectively prevent the moisture and/or oxygen from damaging the organic light-emitting structure 200, the transistor TR, etc. In an exemplary embodiment, for example, the getter 750 may include barium (Ba), calcium (Ca), magnesium (Mg), titanium (Ti), zirconium (Zr), molybdenum (Mo), thorium (Th), cerium (Ce), aluminum (Al), and/or nickel (Ni).

The capping layer 40 may be disposed on the second electrode 24. The capping layer 40 may be substantially disposed in the entire display region 12 to fully cover the second electrode 24. The capping layer 40 may protect the underlying organic light-emitting structure 200, and may provide efficient output of light emitted from the organic light-emitting structure 200.

In exemplary embodiments, the pixel defining layer 30 may be in contact with an end portion 40a of the capping layer 40. When a planar area of the capping layer 40 is larger than that of the second electrode 24, the end portion 40a of the capping layer 40 which corresponds to an edge portion of the capping layer 40 may not be in contact with the second electrode 24. In other words, a bottom surface of the end portion 40a of the capping layer 40 may be in contact with a top surface of the pixel defining layer 30 exposed or uncovered by the second electrode 24. That is, the second electrode 24 may not be overlapped by the edge portion of the capping layer 40.

In exemplary embodiments, the capping layer 40 may include an organic material. In an exemplary embodiment, for example, the capping layer 40 may include at least one of acryl, polyimide, polyamide, and poly(3,4-ethylenedioxythiophene).

The second substrate 50 may be disposed over the capping layer 40 to substantially face the first substrate 10. The second substrate 50 may include a transparent insulation substrate such as a glass substrate, a quartz substrate, a plastic substrate, etc. Alternatively, the second substrate 50 may include a flexible substrate.

Referring to FIG. 4, the pixel defining layer 30 may generate an outgas OG1 due to relatively short-term or long-term chemical dissolution of the pixel defining layer 30 including an organic material. When the end portion 40a of the capping layer 40 is in contact with the pixel defining layer 30, the outgas OG1 may be transferred to within the capping layer 40 from the pixel defining layer 30. The outgas OG1 may be injected into the organic light-emitting layer 22 of the organic light-emitting structure 200 through the capping layer 40, and may degrade the organic light-emitting structure 200, so that a pixel shrinkage may be induced or a lifetime of the pixels may be decreased. From the capping layer 40, the outgas OG1 may pass into the dispersion layer 60 as outgas OG2 via the filling member 70.

The dispersion layer 60 may be disposed on a bottom surface of the second substrate 50. The dispersion layer 60 may absorb the outgas OG2 generated from the pixel defining layer 30. In other words, the dispersion layer 60 may substantially disperse the outgas OG1 which may be transferred to the organic light-emitting layer 22 from the pixel defining layer 30 through the capping layer 40.

In exemplary embodiments, a cross-sectional thickness of the dispersion layer 60 may be in a range of about 54 nanometers (nm) to about 150 nm. The thickness may be taken in a direction perpendicular to the second substrate 50. If the thickness of the dispersion layer 60 is less than about 54 nm, the dispersion layer 60 may not absorb an amount of the outgas enough to disperse the outgas generated from the pixel defining layer 30. If the thickness of the dispersion layer 60 is greater than about 150 nm, a transmittance of the second substrate 50 may be reduced, and a manufacturing cost for the organic light-emitting display device 1 may be increased.

In exemplary embodiments, the dispersion layer 60 may include an organic material. In an exemplary embodiment, for example, the dispersion layer 60 may include at least one of acryl, polyimide, polyamide, and poly(3,4-ethylenedioxythiophene).

In exemplary embodiments, the capping layer 40 and the dispersion layer 60 may include or be formed of substantially the same material. In an exemplary embodiment, for example, the capping layer 40 and the dispersion layer 60 may include at least one of the above mentioned organic materials. When the capping layer 40 and the dispersion layer 60 have substantially the same material, a manufacturing cost for the organic light-emitting display device 1 may be reduced.

In exemplary embodiments, the dispersion layer 60 may be substantially disposed or formed on the entire second substrate 50. In an exemplary embodiment, for example, the dispersion layer 60 may be disposed on an entire bottom surface of the second substrate 50 to correspond to the capping layer 40 that is substantially disposed in the entire display region 12. In some exemplary embodiments, the dispersion layer 60 may be disposed or formed on a portion of the second substrate 50. In an exemplary embodiment, for example, the dispersion layer 60 may be disposed on a portion of the bottom surface of the second substrate 50 to correspond to the first electrode 20.

The filling member 70 may fill a space between the capping layer 40 and the dispersion layer 60. When the space between the capping layer 40 and the dispersion layer 60 is filled by the filling member 70, a durability of the organic light-emitting display device 1 against an impact from an outside may be improved. In exemplary embodiments, the filling member 70 may include silicon. The outgas generated from the pixel defining layer 30 may be transferred to the dispersion layer 60 through the filling member 70 such that the filling member 70 may not include the outgas or the outgas may not remain in the filling member 70.

As mentioned above, the organic light-emitting display device 1 may include the dispersion layer 60 disposed on the bottom surface of the second substrate 50, so that the outgas generated from the pixel defining layer 30 may be transferred to the dispersion layer 60 through the filling member 70, and an amount of the outgas transferred to the organic light-emitting layer 22 through the capping layer 40 may be reduced or effectively prevented.

Therefore, the pixel shrinkage may be not induced, or the lifetime of the pixels may be not decreased.

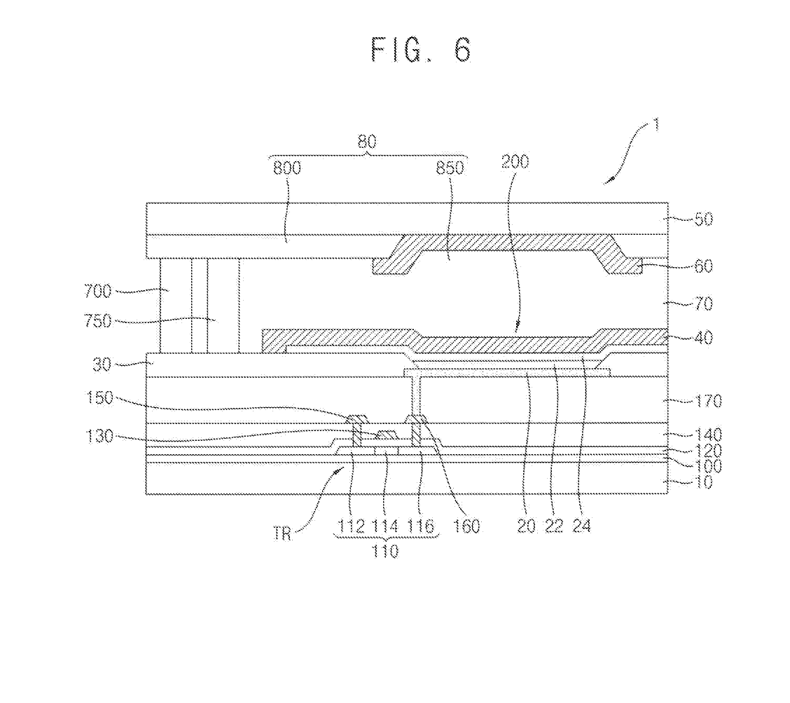

FIGS. 5 and 6 are cross-sectional views illustrating other exemplary embodiments of the organic light-emitting display device in FIG. 1 taken along line II-II′ in FIG. 1.

Referring to FIGS. 5 and 6, an organic light-emitting display device 1 may include a transistor TR, an organic light-emitting structure 200, a pixel defining layer 30 and a capping layer 40 on a first substrate 10, a dispersion layer 60 and a first reflective layer 80 on a second substrate 50, etc. In exemplary embodiments, the organic light-emitting display device 1 may further include a filling member 70. Detailed description on elements in FIGS. 5 and 6 which are substantially the same as or similar to those illustrated with reference to

FIGS. 1 to 3 will not be repeated.

The first reflective layer 80 may be disposed between the second substrate 50 and the dispersion layer 60. The first reflective layer 80 may reflect an external light incident into the organic light-emitting display device 1, so that the organic light-emitting display device 1 may serve as a mirror display device.

In exemplary embodiments, the first reflective layer 80 may include or define an opening portion 850 that corresponds to the first electrode 20 such as at the pixel opening of the pixel defining layer 30, and a reflective portion 800 that surrounds the opening portion 850 such as in a top plan view to correspond to the pixel defining layer 30. Since light may be emitted by the organic light-emitting layer 22 at which the first electrode 20 is disposed, the reflective portion 800 defines the opening portion 850 of the first reflective layer 80 through which light is transmitted at a region that corresponds to the first electrode 20. Since the light may be not emitted at a region in which the pixel defining layer 30 is disposed, the reflective portion 800 that reflects light may be disposed or formed at a region that corresponds to the pixel defining layer 30.

In exemplary embodiments, the first reflective layer 80 may include aluminum (Al), silver (Ag), gold (Au), platinum (Pt), nickel (Ni), copper (Cu), and/or tungsten (W). Particularly, the reflective portion 800 may include the above-described materials.

In exemplary embodiments, as illustrated in FIG. 5, the dispersion layer 60 may be substantially disposed or formed on the entire second substrate 50. In an exemplary embodiment, for example, the dispersion layer 60 may be extended to be disposed under the reflective portion 800 of the first reflective layer 80 and on a bottom surface of the second substrate 50 that corresponds to the opening portion 850 of the first reflective layer 80, to correspond to the capping layer 40 substantially disposed in the entire display region 12. Where the dispersion layer 60 is disposed in emitting and non-emitting (e.g., reflective) regions of the organic light-emitting display device 1, the dispersion layer 60 may transmit an external light for a transmission (or display) function and improve a quality of a mirror for a reflective function of the organic light-emitting display device 1.

In some exemplary embodiments, as illustrated in FIG. 6, the dispersion layer 60 may be disposed or formed at a region that substantially corresponds to the opening portion 850 of the first reflective layer 80, on the second substrate 50. In an exemplary embodiment, for example, the dispersion layer 60 may be disposed on the bottom surface of the second substrate 50 that corresponds to the opening portion 850 of the first reflective layer 80, to correspond to the first electrode 20 disposed on the first substrate 10. The dispersion layer 60 may have a discrete shape which is disposed only at the emitting region of the organic light-emitting display device 1, that is, corresponding to a region at which light is emitted by the organic light-emitting layer 22.

As mentioned above, the organic light-emitting display device 1 may include the first reflective layer 80 that reflects the external light, so that the organic light-emitting display device 1 may be used as a mirror display device. Moreover, the dispersion layer 60 may transmit the external light and improve the quality of the mirror as well as disperse an outgas generated from the pixel defining layer 30.

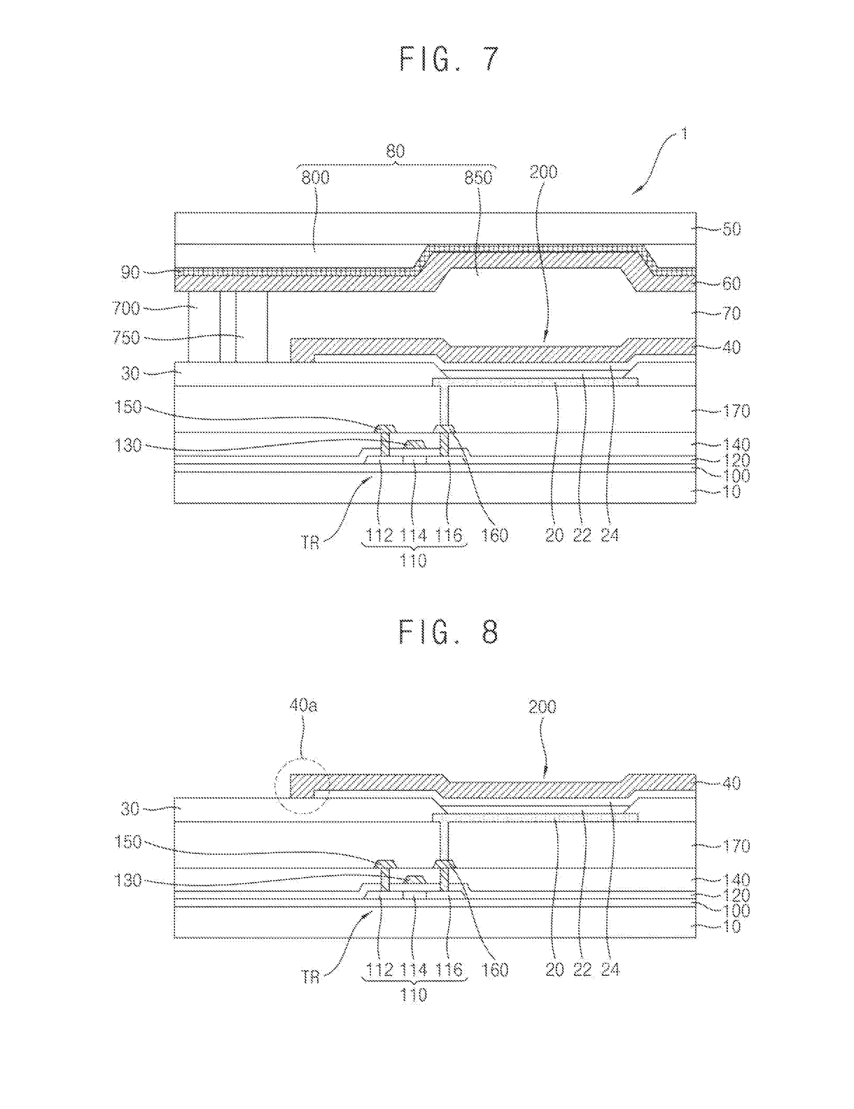

FIG. 7 is a cross-sectional view illustrating still another example of the organic light-emitting display device in FIG. 1 taken along line II-II′ in FIG. 1.

Referring to FIG. 7, an organic light-emitting display device 1 may include a transistor TR, an organic light-emitting structure 200, a pixel defining layer 30 and a capping layer 40 on a first substrate 10, a dispersion layer 60, a first reflective layer 80 and a second reflective layer 90 on a second substrate 50, etc. In exemplary embodiments, the organic light-emitting display device 1 may further include a filling member 70. Detailed description on elements in FIG. 7 which are substantially the same as or similar to those illustrated with reference to FIGS. 1 to 3, and 5 will not be repeated.

The second reflective layer 90 may be disposed between the first reflective layer 80 and the dispersion layer 60. The second reflective layer 90 may transmit an external light incident into the organic light-emitting display device 1 and a light emitted from the organic light-emitting display device 1 to improve a transmittance of the organic light-emitting display device 1.

In exemplary embodiments, the dispersion layer 60 and the second reflective layer 90 may be formed on the substantially entire second substrate 50. In an exemplary embodiment, for example, the second reflective layer 90 may be disposed on a bottom surface of the second substrate 50 to correspond to the capping layer 40 that is disposed in the substantially entire display region 12, and the dispersion layer 60 may be substantially disposed on a bottom surface of the second reflective layer 90.

In exemplary embodiments, the second reflective layer 90 may include silver (Ag) and/or indium tin oxide (“ITO”).

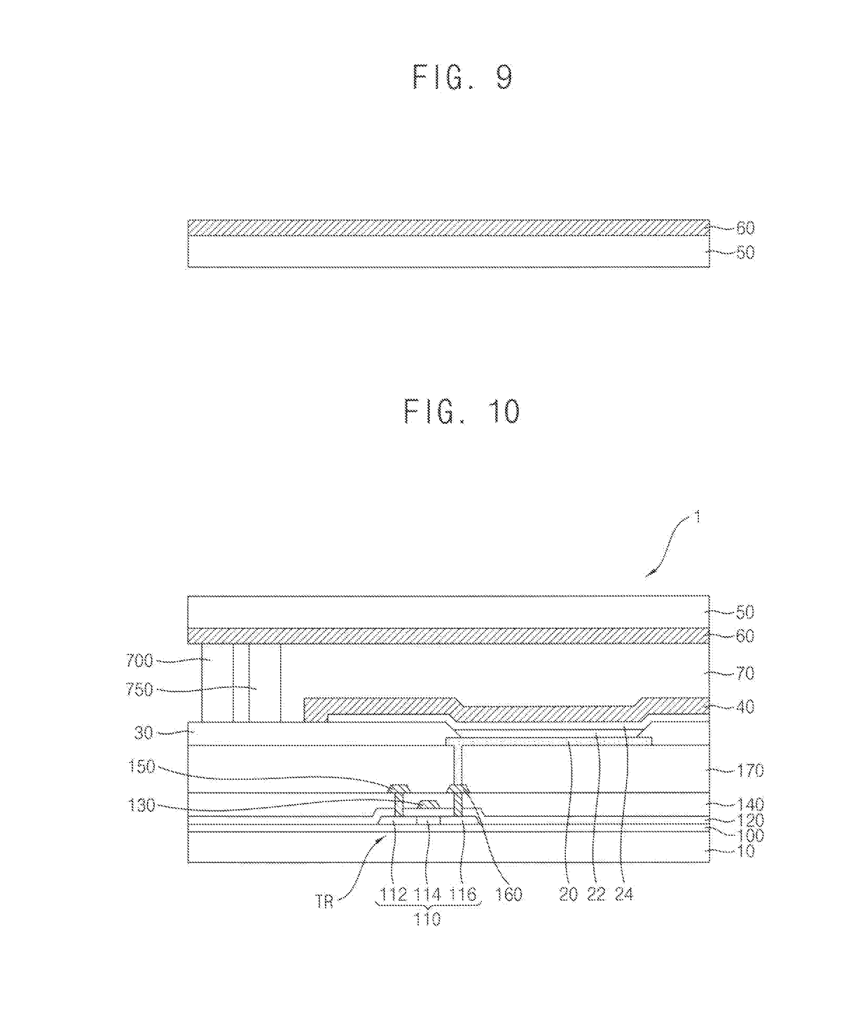

FIGS. 8 to 10 are cross-sectional views illustrating an exemplary embodiment of a method of manufacturing an organic light-emitting display device in accordance with the invention.

Referring to FIG. 8, a first substrate 10 on which a transistor TR and an organic light-emitting structure 200 are formed may be provided. The first substrate 10 may include a transparent insulation substrate such as a glass substrate, a quartz substrate, a plastic substrate, etc. Alternatively, the first substrate 10 may include a flexible substrate.

A buffer layer 100 may be formed on the first substrate 10. In an exemplary embodiment, for example, the buffer layer 100 may be formed by a deposition process or a coating process using a silicon compound such as silicon oxide (SiOx), silicon nitride (SiNx), silicon oxynitride (SiOxNy), etc. The buffer layer 100 may be formed as a single layer structure or a multi-layer structure.

A semiconductor material layer may be formed on the buffer layer 100. The semiconductor material layer may be formed using single crystalline silicon, polycrystalline silicon, or oxide semiconductor. In an exemplary embodiment, for example, when the semiconductor layer includes an oxide semiconductor, the semiconductor material layer may be formed by a sputtering process using a plurality of targets.

The semiconductor material layer may be etched to form an active pattern 110. In an exemplary embodiment, for example, the active pattern 110 may be formed by a photolithography process or an etching process using a hard mask.

A gate insulation layer 120 may be formed on the buffer layer 100 to substantially cover the active pattern 110. In an exemplary embodiment, for example, the gate insulation layer 120 may be formed by a deposition process using a silicon compound such as silicon oxide, silicon nitride, and silicon oxy nitride, or metal oxide such as aluminum oxide, titanium oxide, and hafnium oxide.

A gate electrode 130 may be formed on the gate insulation layer 120 to correspond to a channel region 114 (will be explained below) of the active pattern 110. The gate electrode 130 may be formed over the active pattern 110. In an exemplary embodiment, for example, the gate electrode 130 may be formed using gold (Au), silver (Ag), copper (Cu), nickel (Ni), platinum (Pt), aluminum (Al), molybdenum (Mo) and/or titanium (Ti).

Impurities may be injected to the active pattern 110 by using the gate electrode 130 as an ion injection mask, and then a source region 112 and a drain region 116 of the active pattern 110 may be formed, and the channel region 114 thereof may be defined therebetween.

An insulation interlayer 140 may be formed on the gate insulation layer 120 to substantially cover the gate electrode 130. In an exemplary embodiment, or example, the insulation interlayer 140 may be formed by a deposition process or a coating process using a silicon compound such as silicon oxide, silicon nitride, silicon oxy nitride, etc.

A source electrode 150 and a drain electrode 160 may be formed on the insulation interlayer 140. The source electrode 150 and the drain electrode 160 may be in contact with the source region 112 and drain region 116, respectively, such as by extending through the gate insulation layer 120 and the insulation interlayer 140 at contact holes formed therein. In an exemplary embodiment, for example, the source electrode 150 and the drain electrode 160 may be formed using gold, silver, copper, nickel, platinum, aluminum, molybdenum and/or titanium.

A planarization layer 170 may be formed on the insulation interlayer 140 to substantially cover the source electrode 150 and the drain electrode 160. In an exemplary embodiment, for example, the planarization layer 170 may be formed by a deposition process or a coating process using a silicon compound such as silicon oxide, silicon nitride, silicon oxy nitride, etc. Alternatively, the planarization layer 170 may be formed on the insulation interlayer 140 using an organic material such as polyimide or acryl.

A first electrode 20 may be formed on the planarization layer 170. The first electrode 20 may be in contact with the drain electrode 160 such as by extending through the insulation layer 170 at a contact hole defined therein. In an exemplary embodiment, for example, the first electrode 20 may be formed using silver (Ag), magnesium (Mg), aluminum

(Al), platinum (Pt), gold (Au), nickel (Ni), iridium (Ir), chrome (Cr), indium tin oxide (“ITO”), indium zinc oxide (“IZO”), zinc oxide (ZnO), and/or indium gallium oxide (“IGO”).

A pixel defining layer 30 may be formed on the planarization layer 170 to partially expose the first electrode 20. The pixel defining layer 30 may be formed on the substantially entire first substrate 10. In an exemplary embodiment, for example, the pixel defining layer 400 may be formed using an organic material.

An organic light-emitting layer 22 may be formed on the exposed first electrode 20 and a portion of the pixel defining layer 30. In an exemplary embodiment, when the organic light-emitting layer 22 is formed using an organic material having a relatively low molecular weight, a hole injection layer and a hole transport layer may be formed on the first electrode 20 and the pixel defining layer 30 before forming the organic light-emitting layer 22, and an electron transport layer and an electron injection layer may be formed after forming the organic light-emitting layer 22. In another exemplary embodiment, when the organic light-emitting layer 22 is formed using an organic material having a relatively high molecular weight, a hole transport layer may be formed on the first electrode 20 and the pixel defining layer 30 before forming the organic light-emitting layer 22.

A second electrode 24 may be formed on the organic light-emitting layer 22. The second electrode 24 may be formed on the substantially entire first substrate 10. In an exemplary embodiment, for example, the second electrode 24 may be formed using silver, magnesium, aluminum, platinum, gold, nickel, iridium, chrome, indium tin oxide, indium zinc oxide, zinc oxide, and/or indium gallium oxide.

A capping layer 40 may be formed on the second electrode 24. The capping layer 40 may be formed over the substantially entire first substrate 10 to cover the second electrode 24. In exemplary embodiments, the capping layer 40 may be formed using an organic material. In an exemplary embodiment, for example, the capping layer 40 may be formed using acryl, polyimide, polyamide and/or Poly(3,4-ethylenedioxythiophene).

In exemplary embodiments, an end portion 40a of the capping layer 40 may be formed to be in contact with the pixel defining layer 30. In an exemplary embodiment, for example, a bottom surface of the end portion 40a of the capping layer 40 may be formed to be in contact with a top surface of the pixel defining layer 30 which may be uncovered or exposed by the second electrode 24.

Referring to FIG. 9, a second substrate 50 on which a dispersion layer 60 is formed may be provided. The second substrate 50 may include a transparent insulation substrate such as a glass substrate, a quartz substrate, a plastic substrate, etc. Alternatively, the second substrate 50 may include a flexible substrate.

The dispersion layer 60 may be formed on the second substrate 50. In an exemplary embodiment, for example, the dispersion layer 60 may be formed on the substantially entire second substrate 50. In exemplary embodiments, the dispersion layer 60 may be formed using an organic material. In an exemplary embodiment, for example, the capping layer 40 may be formed using acryl, polyimide, polyamide and/or Poly(3,4-ethylenedioxythiophene).

In exemplary embodiments, the dispersion layer 60 may be formed using substantially the same material as that of the capping layer 40. In an exemplary embodiment, for example, the capping layer 40 and the dispersion layer 60 may be formed using substantially the same and at least one organic material. When the capping layer 40 and the dispersion layer 60 are formed using substantially the same material, a manufacturing cost for the organic light-emitting display device 1 may be reduced.

In exemplary embodiments, the dispersion layer 60 may be formed to have a thickness in a range of about 54 nm to about 150 nm. If the thickness of the dispersion layer 60 is less than about 54 nm, the dispersion layer 60 may not absorb an amount of an outgas enough to disperse the outgas generated from the pixel defining layer 30. If the thickness of the dispersion layer 60 is greater than about 150 nm, a transmittance of the second substrate 50 may be reduced, and a manufacturing cost for the organic light-emitting display device 1 may be increased.

Referring to FIG. 10, the first substrate 10 and the second substrate 20 may be combined to dispose the dispersion layer 60 facing the capping layer 40 with respect to a space formed therebetween. In an exemplary embodiment, for example, a sealing member 700 may be formed on an edge portion of the pixel defining layer 30, and then the second substrate 50 with layers thereon may be combined with the first substrate 10 with layers thereon for the sealing member 700 to be in contact with the dispersion layer 60. In exemplary embodiments, a filling member 70 may be injected into a space between the first substrate 10 and the second substrate 50 to fill a space between the first substrate 10 and the second substrate 50.

The exemplary embodiments of the organic light-emitting display devices and the methods of manufacturing the organic light-emitting display devices according to the invention may be applied to various electronic devices. In an exemplary embodiment, for example, the organic light-emitting display devices may be applied to computers, notebooks, cellular phones, smart phones, smart pads, portable multimedia players, personal digital assistants, MP3 players, digital cameras, video camcorder, etc.

Although a few exemplary embodiments have been described, those skilled in the art will readily appreciate that many modifications are possible in the exemplary embodiments without materially departing from the novel teachings and advantages of the invention.

What is claimed is:

1. An organic light-emitting display device, comprising:
a first substrate;
a first electrode disposed on the first substrate;
a pixel defining layer disposed on the first substrate, the pixel defining layer defining a pixel opening thereof which exposes a portion of the first electrode;
an organic light-emitting layer disposed on the exposed portion of the first electrode;
a second electrode disposed on the organic light-emitting layer;
a capping layer disposed on the second electrode and extending to contact the pixel defining layer;
a second substrate opposite to the first substrate; and
a dispersion layer disposed on a bottom surface of the second substrate to face the pixel defining layer with respect to the capping layer.

2. The organic light-emitting display device of claim 1, wherein the dispersion layer absorbs an outgas generated by the pixel defining layer.

3. The organic light-emitting display device of claim 1, wherein an end portion of the capping layer contacts the pixel defining layer.

4. The organic light-emitting display device of claim 1, wherein a thickness of the dispersion layer is in a range of about 54 nanometers to about 150 nanometers.

5. The organic light-emitting display device of claim 1, wherein the capping layer includes an organic material.

6. The organic light-emitting display device of claim 1, wherein the dispersion layer includes an organic material.

7. The organic light-emitting display device of claim 1, wherein the dispersion layer includes a same material as the capping layer.

8. The organic light-emitting display device of claim 1, wherein the dispersion layer is disposed on an entirety of the bottom surface of the second substrate.

9. The organic light-emitting display device of claim 1, wherein the dispersion layer is disposed on a portion of the bottom surface of the second substrate.

10. The organic light-emitting display device of claim 1, further comprising a first reflective layer disposed between the second substrate and the dispersion layer.

11. The organic light-emitting display device of claim 10, wherein the first reflective layer includes at least one of aluminum (Al), silver (Ag), gold (Au), platinum (Pt), nickel (Ni), copper (Cu) and tungsten (W).

12. The organic light-emitting display device of claim 10, wherein the dispersion layer is continuously disposed on an entirety of the first reflective layer.

13. The organic light-emitting display device of claim 10, wherein the first reflective layer includes a reflective portion corresponding to the pixel defining layer, the reflective portion defining an opening portion of the first reflective layer, the opening portion surrounded by the reflective portion and corresponding to the first electrode.

14. The organic light-emitting display device of claim 13, wherein the dispersion layer is disposed overlapping the opening portion of the first reflective layer and non-overlapping the reflective portion of the first reflective layer.

15. The organic light-emitting display device of claim 10, further comprising a second reflective layer disposed between the first reflective layer and the dispersion layer.

16. The organic light-emitting display device of claim 15, wherein the second reflective layer is disposed on an entirety of the first reflective layer.

17. The organic light-emitting display device of claim 15, wherein the second reflective layer includes at least one of silver (Ag) and indium tin oxide.

18. The organic light-emitting display device of claim 1, wherein the dispersion layer disposed on the bottom surface of the second substrate defines a space with the capping layer,
further comprising a filling member in the space defined between the capping layer and the dispersion layer.

19. The organic light-emitting display device of claim 18, wherein the filling member includes silicon.
